(19) United States
(12) Patent Application Publication
(10) Pub. No.: US 2026/0020203 A1
(43) Pub. Date: Jan. 15, 2026

(54) DISPLAY DEVICE AND ELECTRONIC DEVICE

(71) Applicant: Samsung Display Co., Ltd., Yongin-si (KR)

(72) Inventors: Eun Won SEO, Yongin-si (KR); Joon Ik LEE, Yongin-si (KR); Jun Hee SON, Yongin-si (KR)

(21) Appl. No.: 19/195,153

(22) Filed: Apr. 30, 2025

(30) Foreign Application Priority Data
Jul. 9, 2024 (KR) 10-2024-0090743

(51) Int. Cl. H05K 7/20; G06F 3/041; H05K 5/00; H05K 5/02

(52) U.S. Cl. CPC H05K 7/20963; G06F 3/041; H05K 5/0018; H05K 5/0217; H05K 7/2039; G06F 2203/04102

(57) ABSTRACT

A display device includes: a display panel having a first area, a folding area, and a second area arranged along a first direction, the folding area being configured to be folded with respect to a folding axis defined along a second direction crossing the first direction; a support plate on a rear surface of the display panel, the support plate having a pattern portion overlapping the folding area; a heat dissipation plate on a rear surface of the support plate, the heat dissipation plate having a continuous bending portion; and a first coolant between the bending portion and the support plate.

### CROSS-REFERENCE TO RELATED APPLICATION

The present application claims priority to and the benefit of Korean Patent Application No. 10-2024-0090743, filed on Jul. 9, 2024, in the Korean Intellectual Property Office, the entire disclosure of which is incorporated herein by reference.

### BACKGROUND

### 1. Field

Aspects of embodiments of the present disclosure relate to a display device and an electronic device.

### 2. Description of the Related Art

Recently, as interest in information displays is increased, research and development of display devices have been continuously conducted.

### SUMMARY

Embodiments of the present disclosure provide a display device exhibiting improved heat dissipation characteristics by using a space of a bending portion of a heat dissipation plate.

According to an embodiment of the present disclosure, a display device includes: a display panel having a first area, a folding area, and a second area arranged along a first direction, the folding area being configured to be folded with respect to a folding axis defined along a second direction crossing the first direction; a support plate on a rear surface of the display panel, the support plate having a pattern portion overlapping the folding area; a heat dissipation plate on a rear surface of the support plate, the heat dissipation plate having a continuous bending portion; and a first coolant between the bending portion and the support plate.

The bending portion may be coupled to the support plate.

The bending portion may overlap the folding area.

The bending portion may not overlap the folding area.

The heat dissipation plate may have a lattice portion overlapping the folding area.

The first coolant may overlap the first area and the second area.

The first coolant may not overlap the folding area.

The display device may further include a lower plate on a rear surface of the heat dissipation plate.

The display device may further include a second coolant between the bending portion and the lower plate.

The bending portion may be coupled to the lower plate.

The display device may further include an upper plate between the support plate and the heat dissipation plate.

The bending portion may be coupled to the upper plate.

According to another embodiment of the present disclosure, a display device includes: a display panel having a first area, a folding area, and a second area arranged along a first direction, the folding area being configured to be folded with respect to a folding axis defined along a second direction crossing the first direction; a support plate on a rear surface of the display panel, the support plate having a pattern portion overlapping the folding area; a lower plate on a rear surface of the support plate; a heat dissipation plate between the support plate and the lower plate, the heat dissipation plate having a continuous bending portion; a first flow path between the support plate and the bending portion; and a second flow path between the lower plate and the bending portion.

The display device may further include: a first heat dissipation resin in the first flow path; and a second heat dissipation resin in the second flow path.

The first heat dissipation resin and the second heat dissipation resin may overlap the first area and the second area.

The first heat dissipation resin and the second heat dissipation resin may not overlap the folding area.

The bending portion may include a first bending portion coupled to the support plate and a second bending portion coupled to the lower plate.

The first bending portion and the second bending portion may be alternately arranged.

The first flow path may be between the support plate and the second bending portion.

The second flow path may be between the lower plate and the first bending portion.

According to an embodiment of the present disclosure, an electronic device includes: a display device including: a display panel having a first area, a folding area, and a second area arranged along a first direction, the folding area being configured to be folded with respect to a folding axis defined along a second direction crossing the first direction; a support plate on a rear surface of the display panel, the support plate having a pattern portion overlapping the folding area; a heat dissipation plate on a rear surface of the support plate, the heat dissipation plate having a continuous bending portion; and a first coolant between the bending portion and the support plate.

The electronic device may further include a sensing layer on the display device, and the sensing layer may be configured to receive a user's touch as an input.

The bending portion of the heat dissipation plate may form two adjacent cooling channels separated from each other by the heat dissipation plate.

### BRIEF DESCRIPTION OF THE DRAWINGS

Embodiments of the present disclosure will now be described more fully hereinafter with reference to the accompanying drawings; however, embodiments of the present disclosure may be embodied in different forms, and the present disclosure should not be construed as being limited to the embodiments described herein. Rather, these embodiments are provided so that this disclosure will be thorough and complete, and will fully convey the scope of the present disclosure to those skilled in the art.

FIG. 1 is a plan view of a display device in accordance with an embodiment of the present disclosure in an unfolded state.

FIG. 2 is a side view of the display device shown in FIG. 1 in accordance with an embodiment of the present disclosure in a folded state.

FIG. 3 is a cross-sectional view of a display device in accordance with an embodiment of the present disclosure.

FIGS. 4 and 5 are plan views illustrating a pattern portion of a support plate in accordance with embodiments of the present disclosure.

FIG. 6 is a cross-sectional view of a display device in accordance with an embodiment of the present disclosure.

FIG. 7 is a cross-sectional view of a display device in accordance with an embodiment of the present disclosure.

FIG. 8 is a cross-sectional view of a display device in accordance with an embodiment of the present disclosure.

FIGS. 9 to 11 are plan views illustrating a lattice portion of a heat dissipation plate in accordance with embodiments of the present disclosure.

FIG. 12 is a cross-sectional view of a display device in accordance with an embodiment of the present disclosure.

FIG. 13 is a block diagram of an electronic device according to an embodiment.

FIG. 14 shows schematic views of various embodiments of an electronic device.

### DETAILED DESCRIPTION

Aspects and features of the present disclosure, and methods of achieving them, will be described by referring to embodiments described below in detail together with the accompanying drawings. However, the present disclosure is not limited to the embodiments disclosed herein and may be implemented in various forms. These embodiments are provided by way of example only so that a person of ordinary skilled in the art can fully understand the aspects and features in the present disclosure and the scope thereof. Therefore, the present disclosure is defined by the scope of the appended claims and their equivalents.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Hereinafter, embodiments of the present disclosure will be described in more detail with reference to the accompanying drawings.

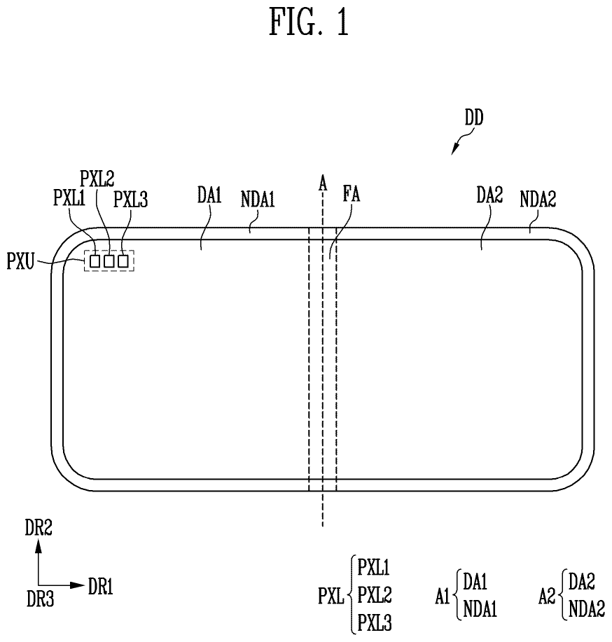

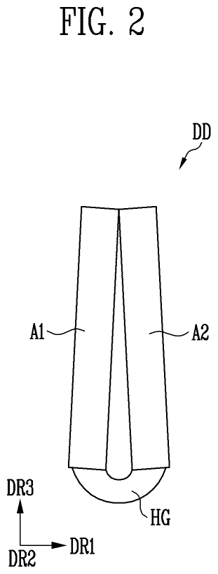

FIG. 1 is a plan view of a display device in accordance with an embodiment of the present disclosure in an unfolded state. FIG. 2 is a side view of the display device shown in FIG. 1 in accordance with an embodiment of the present disclosure in a folded state. In FIGS. 1 and 2, a foldable display device or a foldable display panel is illustrated as an example of the display device DD.

Referring to FIGS. 1 and 2, the display device DD may have a first area A1, a second area A2, and/or a folding area FA. The folding area FA may be located between the first area A1 and the second area A2. The first area A1, the folding area FA, and the second area A2 may be sequentially arranged along a first direction DR1. The display device DD may be folded or unfolded at the folding area FA with respect to a folding axis A (or folding line) extending in a second direction DR2 crossing (e.g., intersecting) the first direction DR1.

When the display device DD is in a folded state, the first area A1 and the second area A2 may face each other (see, e.g., FIG. 2). In an example, the first area A1 and the second area A2 may be coupled to a hinge device HG located at the folding axis A to rotate with respect to the hinge device HG. The first area A1 and the second area A2 may have shapes that are symmetrical to each other, but the present disclosure is not limited thereto.

The hinge device HG may allow a display panel PD (or the display device DD) to be folded or unfolded with respect to the folding axis A. The hinge device HG may be configured to be rotatable with respect to the folding axis A.

When the display device DD is in an unfolded state, the hinge device HG may be covered by the first area A1 and second area A2 such that it is not exposed. When the display device DD is in the folded state, the hinge device HG may be at least partially exposed to the outside while the first area A1 and the second are A2 rotate.

The first area A1 may have a first display area DA1 in which an image is displayed and a first non-display area NDA1 in which the image is not displayed. The first non-display area NDA1 may be disposed at the periphery of (e.g., may surround a periphery of) the first display area DA1.

The second area A2 may have a second display area DA2 in which an image is displayed and a second non-display area NDA2 in which the image is not displayed. The second non-display area NDA2 may be disposed at the periphery of (e.g., may surround a periphery of) the second display area DA2.

The first display area DA1, the second display area DA2, and/or the folding area FA may constitute a screen on which an image is displayed, and the first non-display area NDA1 and the second non-display area NDA2 may be the other area except the first display area DA1, the second display area DA2, and/or the folding area FA.

For convenience of description, in FIG. 1, a structure of the display device DD will be briefly illustrated based on the first display area DA1, the second display area DA2, and the folding area FA. However, in some embodiments, at least one driving circuit (e.g., at least one of a scan driver and a data driver), lines, and/or pads may be further disposed in the display device DD.

A pixel unit PXU may be disposed in the first display area DA1, the second display area DA2, and/or the folding area FA. The pixel unit PXU may include a first pixel PXL1, a second pixel PXL2, and/or a third pixel PXL3. Hereinafter, when at least one pixel from among the first pixel PXL1, the second pixel PXL2, and the third pixel PXL3 is arbitrarily designated or when two or more pixels (e.g., two or more kinds of pixels) from among the first pixel PXL1, the second pixel PXL2, and the third pixel PXL3 are inclusively designated, the corresponding pixel or the corresponding pixels will be referred to as a “pixel PXL” or “pixels PXL.”

The pixels PXL may be regularly arranged according to a stripe structure, a PENTILE® (a registered trademark of Samsung Display Co., Ltd.) structure, or the like. However, the arrangement structure of the pixels PXL is not limited thereto, and the pixels PXL may be arranged in the display area DA by using various structures and/or methods.

In some embodiments, two or more pixels PXL emitting light of different colors may be disposed in the first display area DA1, the second display area DA2, and/or the folding area FA. In an example, first pixels PXL1 emitting light of a first color, second pixels PXL2 emitting light of a second color, and third pixels PXL3 emitting light of a third color may be arranged in the first display area DA1, the second display area DA2, and/or the folding area FA. For example, the first pixel PXL1 may be a red pixel emitting red light, the second pixel PXL2 may be a green pixel emitting green light, and the third pixel PXL3 may be a blue pixel emitting blue light. However, the present disclosure is not limited thereto.

At least one first pixel PXL1, at least one second pixel PXL2, and at least one third pixel PXL3, which are disposed adjacent to each other, may constitute one pixel unit PXU capable of emitting light of various colors. Although an embodiment in which the pixel unit PXU includes one first pixel PXL1, one second pixel PXL2, and one third pixel PXL3 is illustrated in FIG. 1, the present disclosure is not limited thereto, and the pixel unit PXU may include one first pixel PXL1, two second pixels PXL2, and one third pixel PXL3, as another example.

The first pixel PXL1, the second pixel PXL2, and the third pixel PXL3 may have, as light sources, a first light emitting element, a second light emitting element, and a third light emitting element, to emit light of the first color, light of the second color, and light of the third color, respectively. However, the color of light emitted from each pixel PXL may be variously changed.

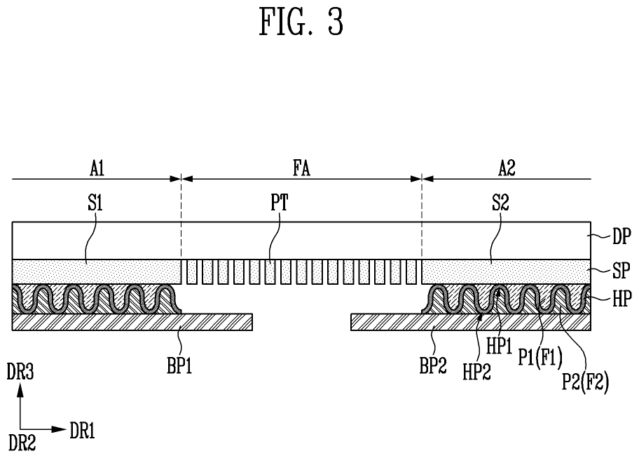

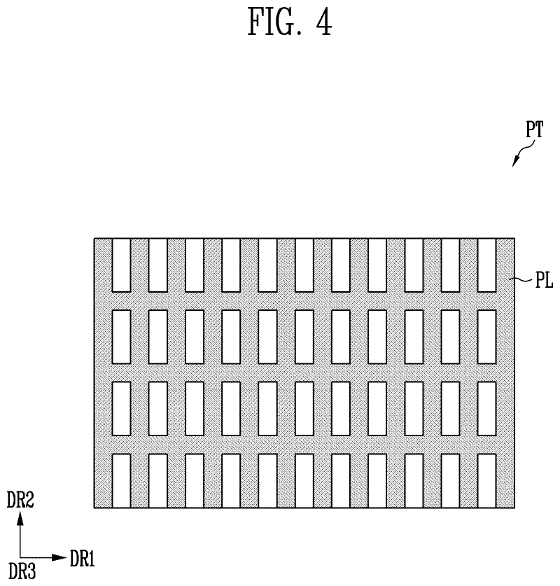

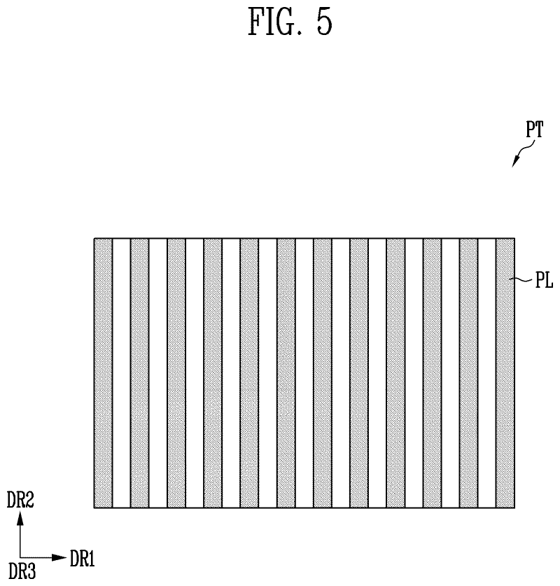

FIG. 3 is a cross-sectional view of a display device in accordance with an embodiment of the present disclosure. FIGS. 4 and 5 are plan views illustrating a pattern portion of a support plate in accordance with embodiments of the present disclosure.

Referring to FIGS. 1 to 5, the display device DD may include a display panel DP, a support plate SP, a heat dissipation plate HP, and/or lower plates BP1 and BP2.

The display panel DP may be folded or unfolded with respect to (e.g., about) the folding axis A. The display panel DP may have a first area A1, a second area A2, and a folding area FA. The folding area FA may be located between the first area A1 and the second area A2. The first area A1, the folding area FA, and the second area A2 may be sequentially arranged along the first direction DR1. The folding area FA may be folded or unfolded with respect to the folding axis A (or folding line) extending in the second direction DR2 crossing (e.g., intersecting) the first direction DR1.

The display panel DP may display various content (e.g., text, an image, a video, an icon, a symbol, and the like) to a user. In some embodiments, the display panel DP may include a sensing layer and a window layer provided on the sensing layer. The sensing layer and the window layer may be attached to each other by a Pressure Sensitive Adhesive (PSA).

The window layer may include a transparent plastic film. The plastic film may include, for example, a polyimide or polyethylene terephthalate (PET) film. In an embodiment, the window layer may include (e.g., may be formed with) plastic films. The plastic films may be attached to each other by the PSA.

The display panel DP may include a flexible substrate, display elements coupled on (or formed on) the substrate, at least one conductive line which is coupled to the substrate and is electrically connected to the display elements, and/or a thin film encapsulation layer. The substrate may be made of a flexible plastic material. However, the present disclosure is not limited thereto, and the substrate may be provided with various materials having flexible properties.

The display elements may be disposed on the substrate and may form a plurality of pixels PXL. For example, the display elements may be arranged in a matrix form on the substrate to form pixels PXL of the display panel DP. In an example, the display elements may include an Organic Light Emitting Diode (OLED), but the present disclosure is not limited thereto.

The conductive line may include at least one gate signal line or at least one data signal line. The conductive line may include gate signal lines and data signal lines. The gate signal lines and the data signal lines may be arranged in a matrix form, and the display elements may be aligned while being disposed adjacent to points at which the lines cross (e.g., intersect) each other, to be electrically connected to the lines.

The thin film encapsulation layer may cover the substrate, the display elements, and/or the conductive line, thereby preventing oxygen and moisture from being introduced from the outside. The thin film encapsulation layer may be formed by alternately stacking at least one organic layer and at least one inorganic layer. An uppermost layer exposed to the outside in the thin film encapsulation layer may be formed with an inorganic layer to prevent moisture infiltration, but the present disclosure is not limited thereto.

In some embodiments, the display panel DP may further include a polarizing film. The polarizing film may reduce a thickness thereof while exhibiting a flexible characteristic and may improve the visibility of an image. Also, the display panel DP may further include a phase retardation film. The phase retardation film may change linearly polarized light to circularly polarized light or may change circularly polarized light to linearly polarized light. In some embodiments, the display panel DP may further include a cushion layer attached by a tape or a PSA.

The support plate SP may be disposed on a rear surface of the display panel DP. The support plate SP may be disposed on the rear surface of the display panel DP to support the display panel DP and reinforce (or improve) rigidity. The support plate SP may be formed of carbon fiber reinforcement plastic, glass fiber reinforcement plastic, and/or stainless steel, but the present disclosure is not limited thereto.

The support plate SP may have a first support portion S1, a second support portion S2, and/or a pattern portion PT. The pattern portion PT may be located between the first support portion S1 and the second support portion S2. The first support portion S1, the pattern portion PT, and the second support portion S2 may be sequentially arranged along the first direction DR1. The pattern portion PT may be folded or unfolded with respect to the folding axis A (or folding line) extending in the second direction DR2 crossing (e.g., intersecting) the first direction DR1.

The first support portion S1 may overlap the first area A1. For example, the first support portion S1 may overlap the first area A1 in a third direction DR3 in the unfolded state. The second support portion S2 may overlap the second area A2. For example, the second portion S2 may overlap the second area A2 in the third direction DR3 in the unfolded state. In some embodiments, the first support portion S1 and/or the second support portion S2 may partially overlap the folding area FA, but the present disclosure is not limited thereto.

The pattern portion PT may overlap the folding area FA. The pattern portion PT may reduce or minimize deformation of the display panel DP in the folding area FA. Accordingly, although the display device DD is repeatedly folded or unfolded, a crease phenomenon is reduced or minimized, thereby improving visibility.

The pattern portion PT may have opening patterns on a plane. The opening patterns in the pattern portion PT may have the shape of a penetration hole (e.g., a penetration opening or through-hole) penetrating (e.g., extending through) the support plate SP.

The opening patterns in the pattern portion PT may have a lattice shape on a plane as shown in, for example, FIG. 4. In another embodiment, the opening patterns of the pattern portion PT may have a shape in which slits are successively disposed on a plane as shown in, for example, FIG. 5. However, the planar shape of the opening patterns in the pattern portion PT is not limited to the embodiments illustrated in FIGS. 4 and 5 and may be variously changed in various embodiments.

Although an embodiment in which the pattern portion PT has opening patterns is illustrated in FIGS. 3 to 5, the present disclosure is not limited thereto. In another embodiment, the pattern portion PT may further include recessed patterns. For example, the recessed patterns in the pattern portion PT may have a half-cut shape on a section (e.g., in a cross-section). The recessed patterns in the pattern portion PT may have a shape recessed in the third direction DR3 from a rear surface of the support plate SP on a section. A depth of the recessed patterns in the pattern portion PT in the third direction DR3 may be smaller than a thickness of the support plate SP in the third direction DR3.

Referring back to FIG. 3, the heat dissipation plate HP may be disposed on the rear surface of the support plate SP. The heat dissipation plate HP may be disposed between the support plate SP and the lower plates BP1 and BP2. In an embodiment, the heat dissipation plate HP may overlap the first are A1 and the second area A2 in the third direction DR3 in the unfolded state. The heat dissipation plate HP may not overlap the folding area FA. For example, the heat dissipation plate HP may not overlap the folding area FA in the third direction DR3 in the unfolded state. The heat dissipation plate HP may be formed of a material such as copper (Cu) or graphite, but the present disclosure is not limited thereto.

The heat dissipation plate HP may have continuous bending portions HP1 and HP2. In an embodiment, the bending portions HP1 and HP2 may overlap the first area A1 and the second area A2. For example, the bending portions HP1 and HP2 may overlap the first area A1 and the second are A2 in the third direction DR3 in the unfolded state. The bending portions HP1 and HP2 may not overlap the folding area FA. For example, the bending portions HP1 and HP2 may not overlap the folding area FA in the third direction DR3 in the unfolded state.

At least one bending portion HP1 and HP2 may be coupled to the support plate SP. For example, the bending portions HP1 and HP2 may have first bending portions HP1 coupled to the rear surface of the support plate SP.

At least one bending portion HP1 and HP2 may be coupled to the lower plates BP1 and BP2. For example, the bending portions HP1 and HP2 may have second bending portions HP2 coupled to top surfaces of the lower plates BP1 to BP2.

The first and second bending portions HP1 and HP2 may be alternately arranged. In an embodiment, the bending portions HP1 and HP2 of the heat dissipation plate HP may have a wave shape or a bent S-shape as shown in FIG. 3. However, the present disclosure is not limited thereto, and the bending portions HP1 and HP2 of the heat dissipation plate HP may have various bending shapes, such as a trapezoidal shape and a rectangular shape.

In an embodiment, the support plate SP and the first bending portions HP1 may be bonded to each other by, for example, laser welding, but the present disclosure is not limited thereto. The lower plates BP1 and BP2 and the second bending portions HP2 may be bonded to each other by, for example, laser welding, but the present disclosure is not limited thereto.

The heat dissipation plate HP may include a cooling flow path P1 and P2. The cooling flow path P1 and P2 may provide a path through which a coolant F1 and F2 can circulate inside (e.g., through) the heat dissipation plate HP.

The coolant F1 and F2 may diffuse or cool heat emitted from the display panel DP while circulating inside the heat dissipating plate HP, thereby preventing heat from concentrating at a specific portion of the display device DD and improving heat dissipation performance.

In an embodiment, the heat dissipation plate HP may efficiently circulate heat by using a phase change of the coolant F1 and F2. For example, the coolant F1 and F2 injected into the cooling flow path P1 and P2 of the vacuum sealed heat dissipation plate HP may evaporate by absorbing heat at a high temperature portion and then condense after moving to a low temperature portion to emit heat so that heat can be rapidly transferred. In an example, the heat dissipation plate HP may be a Pulsating Heat Pipe (PHP) through which heat at an evaporating portion is moved to a condensing portion while a liquid phase and a gas phase self-pulsate, but the present disclosure is not limited thereto.

In an embodiment, the cooling flow path P1 and P2 may overlap the first area A1 and the second area A2. For example, the cooling flow path P1 and P2 may overlap the first area A1 and the second area A2 in the third direction DR3 in the unfolded state. The cooling flow path P1 and P2 may not overlap the folding area FA in the third direction DR3.

The cooling flow path P1 and P2 may have a first flow path P1 and a second flow path P2, which are separated from each other by the heat dissipation plate HP. The first flow path P1 may be located between the support plate SP and the heat dissipation plate HP. For example, the first flow path P1 may be disposed between the rear surface of the support plate SP and a top surface of the heat dissipation plate HP. The first flow path P1 may refer to a space between the rear surface of the support plate SP and the top surface of the heat dissipation plate HP. The first flow path P1 may be located in the second bending portion HP2. The first flow path P1 may be located between the support plate SP and the second bending portion HP2 of the heat dissipation plate HP. For example, the first flow path P1 may refer to a space between the support plate SP and the second bending portion HP2 of the heat dissipation plate HP.

The second flow path P2 may be located between the lower plates BP1 and BP2 and the heat dissipation plate HP. For example, the second flow path P2 may be located between the top surfaces of the lower plates BP1 and the BP2 and a rear surface of the heat dissipation plate HP. The second flow path P2 may refer to a space between the top surfaces of the lower plates BP1 and BP2 and the rear surface of the heat dissipation plate HP. The second flow path P2 may be located in the first bending portion HP1. The second flow path P2 may be located between the lower plates BP1 and BP2 and the first bending portion HP1 of the heat dissipation plate HP. For example, the second flow path P2 may refer to a space between the lower plates BP1 and BP2 and the first bending portion HP1 of the heat dissipation plate HP.

The coolant F1 and F2 may include a first coolant F1 provided in the first flow path P1 and a second coolant F2 provided in the second flow path P2.

In an embodiment, the coolant F1 and F2 may overlap the first area A1 and the second area A2. For example, the coolant F1 and F2 may overlap the first area A1 and the second area A2 in the third direction DR3 in the unfolded state. The coolant F1 and F2 may not overlap the folding area FA. For example, the coolant F1 and F2 may not overlap the folding area FA in the third direction DR3 in the unfolded state.

The first coolant F1 and the second coolant F2 may be separated from each other by the heat dissipation plate HP. The first coolant F1 may be directly introduced into the space between the support plate SP and the second bending portion HP2 of the heat dissipation plate HP. The first coolant F1 may be between the rear surface of the support plate SP and the top surface of the heat dissipation plate HP.

The second coolant F2 may be directly introduced into the space between the lower plates BP1 and BP2 and the first bending portion HP1 of the heat dissipation plate HP. The second coolant F2 may be between the top surfaces of the lower plates BP1 and BP2 and the rear surface of the heat dissipation plate HP.

In an embodiment, a general cooling water or a refrigerant gas may be used as the coolant F1 and F2, but the coolant F1 and F2 may be variously changed in other embodiments. The first coolant F1 and the second coolant F2 may include the same material, but the present disclosure is not limited thereto.

In an embodiment, the heat dissipation plate HP may further include a coolant temperature adjuster and/or a mass flow controller. The coolant temperature adjuster may adjust a temperature of the coolant F1 and F2 input to the cooling flow path P1 and P2.

The mass flow controller may measure and control a flow rate of the coolant F1 and F2 input to the cooling flow path P1 and P2. The coolant temperature adjuster and/or the mass flow controller may be omitted in some embodiments.

In accordance with the above-described embodiment, the cooling flow path P1 and P2 is formed by using the bending portions HP1 and HP2 of the heat dissipation plate HP, and the coolant F1 and F2 is provided in the cooling flow path P1 and P2, respectively, so that heat dissipation characteristics of the display device can be improved. Accordingly, a product thickness and a product weight can be decreased while reducing or minimizing heat generation of the display device DD.

The lower plates BP1 and BP2 may be disposed on the rear surface of the heat dissipation plate HP. The lower plates BP1 and BP2 may include a metal material having high thermal conductivity to absorb heat from the outside and discharge heat to the outside. The lower plates BP1 and BP2 may be coupled to the hinge device HG to be folded or unfolded with respect to the folding axis A.

The lower plates BP1 and BP2 may include a first lower plate BP1 overlapping the first area A1 and a second lower plate BP2 overlapping the second area A2. The lower plates BP1 and BP2 may partially overlap the folding area FA, but the present disclosure is not limited thereto. The first lower plate BP1 and the second lower plate BP2 may be spaced apart from each other with the folding axis A interposed therebetween.

The first lower plate BP1 may overlap the first support portion S1. For example, the first lower plate BP1 may overlap the first support portion S1 in the third direction DR3 in the unfolded state. The second lower plate BP2 may overlap the second support portion S2. For example, the second lower plate BP2 may overlap the second support portion S2 in the third direction DR3 in the unfolded state. The lower plates BP1 and BP2 may partially overlap the pattern portion PT. For example, the lower plates BP1 and BP2 may partially overlap the pattern portion PT in the third direction DR3 in the unfolded state, but the present disclosure is not limited thereto.

In some embodiments, the display device DD may further include a digitizer and/or a housing. The digitizer may be disposed on the rear surface of the display panel DP. The housing may be disposed on the rear surface of the display panel DP. When the digitizer is provided on the rear surface of the display panel DP, the housing may be disposed on a rear surface of the digitizer. The display panel DP may be accommodated in the housing. The housing may be folded or unfolded with respect to the folding axis A by the hinge device HG.

Hereinafter, another embodiment of the present disclosure will be described. In the following embodiment, components that are identical to or substantially similar to components that have been described above are designated by like reference numerals, and overlapping descriptions may be omitted or simplified.

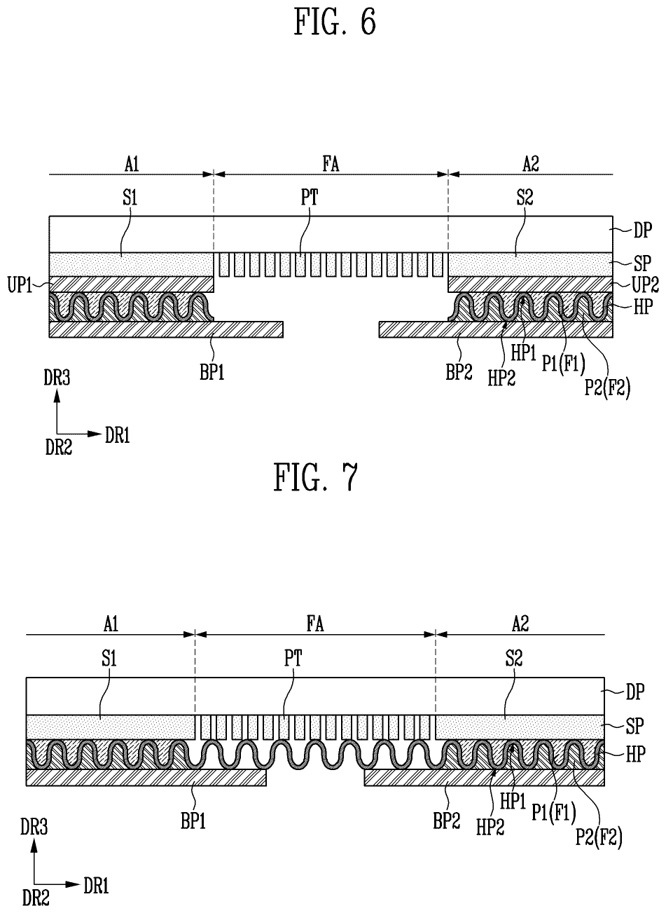

FIG. 6 is a cross-sectional view of a display device in accordance with an embodiment of the present disclosure.

Referring to FIG. 6, the display device DD may further include upper plates UP1 and UP2 disposed between the support plate SP and the heat dissipation plate HP. The upper plates UP1 and UP2 may include a metal material having high thermal conductivity to absorb heat from the outside and discharge heat to the outside.

The upper plates UP1 and UP2 may include a first upper plate UP1 overlapping the first area A1 and a second upper plate UP2 overlapping the second area A2. For example, the first upper plate UP1 may overlap the first area A1 in the third direction DR3 in the unfolded state. The second upper plate UP2 may overlap the second area A2 in the third direction DR3 in the unfolded state. The upper plates UP1 and UP2 may not overlap the folding area FA. For example, the upper plates UP1 and UP2 may not overlap the folding area FA in the unfolded state, but the present disclosure is not limited thereto. The first upper plate UP1 and the second upper plate UP2 may be spaced apart from each other with the folding axis A therebetween.

The first upper plate UP1 may overlap the first support portion S1. For example, the first upper plate UP1 may overlap the first support portion S1 in the third direction DR3 in the unfolded state. The second upper plate UP2 may overlap the second support portion S2. For example, the second upper plate UP2 may overlap the second support portion S2 in the third direction DR3 in the unfolded state. The upper plates UP1 and UP2 may not overlap the pattern portion PT. For example, the upper plates UP1 and UP2 may not overlap the pattern portion PT in the third direction DR3 in the unfolded state, but the present disclosure is not limited thereto.

The first upper plate UP1 may overlap the first lower plate BP1. For example, the first upper plate UP1 may overlap the first lower plate BP1 in the third direction DR3 in the unfolded state. The second upper plate UP2 may overlap the second lower plate BP2. For example, the second upper plate UP2 may overlap the second lower plate BP2 in the third direction DR3 in the unfolded state.

The heat dissipation plate HP may be disposed between the upper plates UP1 and UP2 and the lower plates BP1 and BP2. At least one bending portion HP1 and HP2 may be coupled to the upper plates UP1 and UP2. For example, the bending portions HP1 and HP2 may include first bending portions HP1 coupled to rear surfaces of the upper plates UP1 and UP2.

At least one bending portion HP1 and HP2 may be coupled to the lower plates BP1 and BP2. For example, the bending portions HP1 and HP2 may include second bending portions HP2 coupled to the top surfaces of the lower plates BP1 and BP2.

In an embodiment, the upper plates UP1 and UP2 and the first bending portions HP1 may be bonded to each other by, for example, laser welding, but the present disclosure is not limited thereto. The lower plates BP1 and BP2 and the second bending portions HP2 may be bonded to each other by, for example, laser welding, but the present disclosure is not limited thereto.

A first flow path P1 may be located between the upper plates UP1 and UP2 and the heat dissipation plate HP. For example, the first flow path P1 may be located between the rear surfaces of the upper plates UP1 and UP2 and the top surface of the heat dissipation plate HP. The first flow path P1 may refer to a space between the rear surfaces of the upper plates UP1 and UP2 and the top surface of the heat dissipation plate HP. The first flow path P1 may be located between the upper plates UP1 and UP2 and the second bending portion HP2 of the heat dissipation plate HP. For example, the first flow path P1 may refer to a space between the upper plates UP1 and UP2 and the second bending portion HP2 of the heat dissipation plated HP.

A second flow path P2 may be located between the lower plates BP1 and BP2 and the heat dissipation plate HP. For example, the second flow path P2 may be located between the top surfaces of the lower plates BP1 and BP2 and the rear surface of the heat dissipation plate HP. The second flow path may refer to a space between the top surfaces of the lower plates BP1 and BP2 and the rear surface of the heat dissipation plate HP. The second flow path P2 may be located between the lower plates BP1 and BP2 and the first bending portion HP1 of the heat dissipation plate HP. The second flow path P2 may refer to a space between the lower plates BP1 and BP2 and the first bending portion HP1 of the heat dissipation plate HP.

The coolant F1 and F2 may include a first coolant F1 provided in the first flow path P1 and a second coolant F2 provided in the second flow path P2. In an embodiment, the coolant F1 and F2 may overlap the first area A1 and the second area A2. The coolant F1 and F2 may not overlap the folding area FA.

The first coolant F1 may be directly introduced into the space between the upper plates UP1 and UP2 and the second bending portion HP2 of the heat dissipation plate HP. The first coolant F1 may be between the rear surfaces of the upper plates UP1 and UP2 and the top surface of the heat dissipation plate HP.

The second coolant F2 may be directly introduced into the space between the lower plates BP1 and BP2 and the first bending portion HP1 of the heat dissipation plate HP. The second coolant F2 may be between the top surfaces of the lower plates BP1 and BP2 and the rear surface of the heat dissipation plate HP.

A general cooling water or a refrigerant gas may be used as the coolant F1 and F2, but the coolant F1 and F2 may be variously changed in various embodiments. The first coolant F1 and the second coolant F2 may include the same material, but the present disclosure is not limited thereto.

FIG. 7 is a cross-sectional view of a display device in accordance with an embodiment of the present disclosure.

Referring to FIG. 7, a heat dissipation plate HP may overlap the first area A1, the second area A2, and the folding area FA. For example, the heat dissipation plate HP may overlap the first area A1, the second area A2, and the folding area FA in the third direction DR3 in the unfolded state. In an embodiment, the heat dissipation plate HP may entirely overlap the first area A1, the second area A2, and the folding area FA. For example, the heat dissipation plate HP may be entirely formed on (e.g., may extend entirely across) the rear surface of the display panel DP and/or the support plate SP.

Bending portions HP1 and HP2 may overlap the first area A1, the second area A2, and the folding area FA. For example, the bending portions HP1 and HP2 may overlap the first area A1, the second area A2, and the folding area FA in the third direction DR3 in the unfolded state. In an embodiment, the bending portions HP1 and HP2 may entirely overlap the first area A1, the second area A2, and the folding area FA. For example, the bending portions HP1 and HP2 may be continuously formed on the rear surface of the display panel DP and/or the support plate SP.

In an embodiment, the cooling flow path P1 and P2 may not overlap the folding area FA. For example, the cooling flow path P1 and P2 may not overlap the folding area FA in the third direction DR3 in the unfolded state. For example, the cooling flow path P1 and P2 may partially formed in the first area A1 and the second area A2. Accordingly, the coolant F1 and F2 may not overlap the folding area FA. For example, the coolant F1 and F2 may not overlap the folding area FA in the third direction DR3 in the unfolded state. For example, the coolant F1 and F2 may be partially provided in the first area A1 and the second area A2.

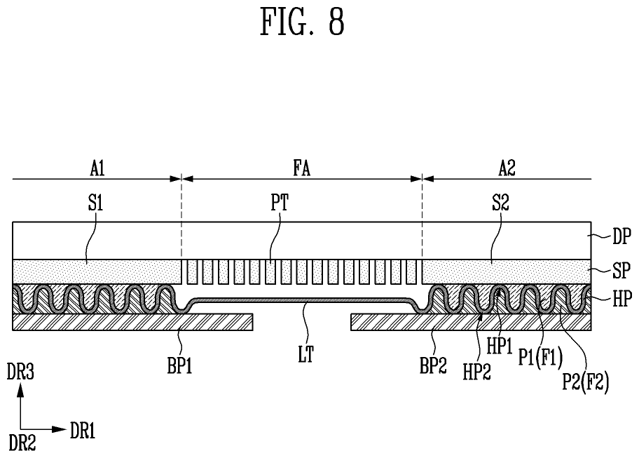

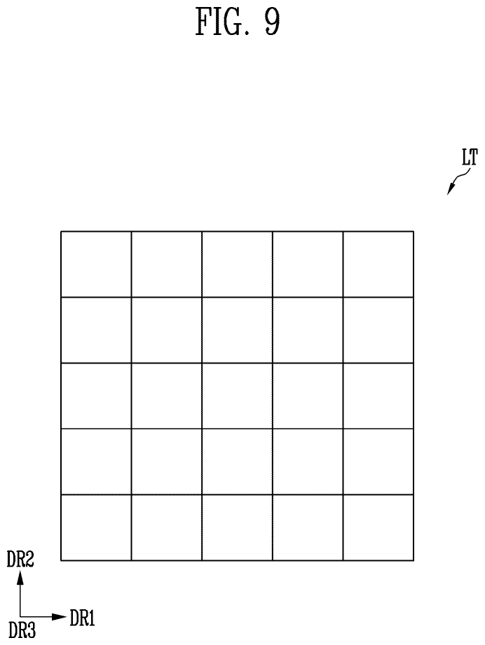

FIG. 8 is a cross-sectional view of a display device in accordance with an embodiment of the present disclosure. FIGS. 9 to 11 are plan views illustrating a lattice portion of a heat dissipation plate in accordance with embodiments of the present disclosure.

Referring to FIGS. 8 to 11, a heat dissipation plate HP may include a lattice portion LT. The lattice portion LT may overlap the folding area FA. For example, the lattice portion LT may overlap the folding area FA in the third direction DR3 in the unfolded state. The lattice portion LT may not overlap the first area A1 and the second area A2. For example, the lattice portion LT may not overlap the first area A1 and the second area A2 in the third direction DR3 in the unfolded state. For example, the lattice portion LT may be partially formed in the folding area FA.

Bending portions HP1 and HP2 may overlap the first area A1 and the second area A2. For example, the bending portions HP1 and HP2 may overlap the first area A1 and the second area A2 in the third direction DR3 in the unfolded state. The bending portions HP1 and HP2 may not overlap the folding area FA. For example, the bending portions HP1 and HP2 may not overlap the first area A1 and the second area A2 in the third direction DR3 in the unfolded state. For example, the bending portions HP1 and HP2 may be partially formed in the first area A1 and the second area A2. Accordingly, cooling flow path P1 and P2 may be partially formed in the first area A1 and the second area A2, and coolant F1 and F2 may be partially provided in the first area A1 and the second area A2.

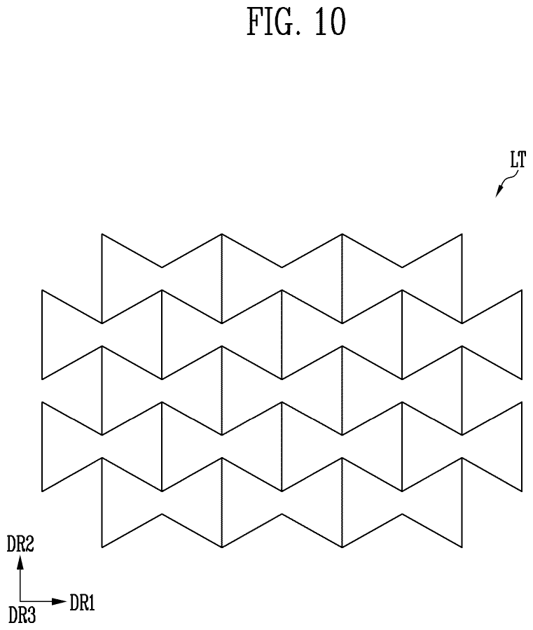

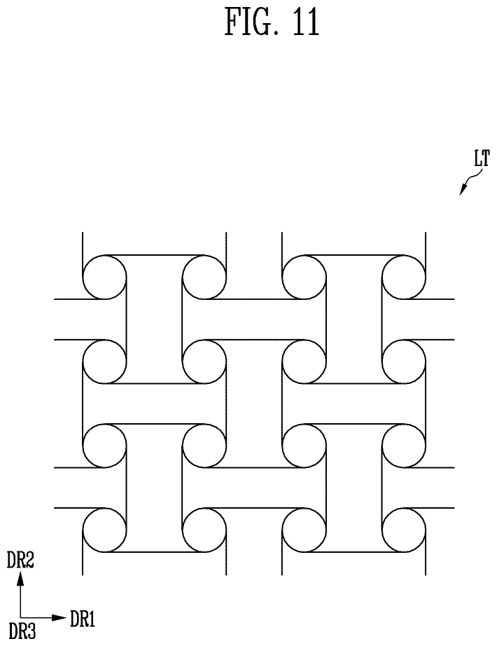

The lattice portion LT may have lattice patterns on a plane. For example, the lattice patterns in the lattice portion LT may have a shape in which a line extending along the first direction DR1 and a line extending along the second direction are repeatedly arranged as shown in, for example, FIG. 9. In another embodiment, the lattice patterns in the lattice portion LT may have a shape in which a polygon is repeatedly arranged along the first direction DR1 and/or the second direction DR2 as shown in, for example, FIG. 10. In another embodiment, the lattice patterns in the lattice portion LT may have a shape in which a circle is repeatedly arranged along the first direction DR1 and/or the second direction DR2 and a line extending along the first direction DR1 and/or the second direction DR2 is repeatedly arranged between circles spaced apart from each other as shown in, for example, FIG. 11. However, the planar shape of the lattice patterns in the lattice portion LT is not limited to the embodiments illustrated in FIGS. 9 to 11 and may be variously changed in various embodiments.

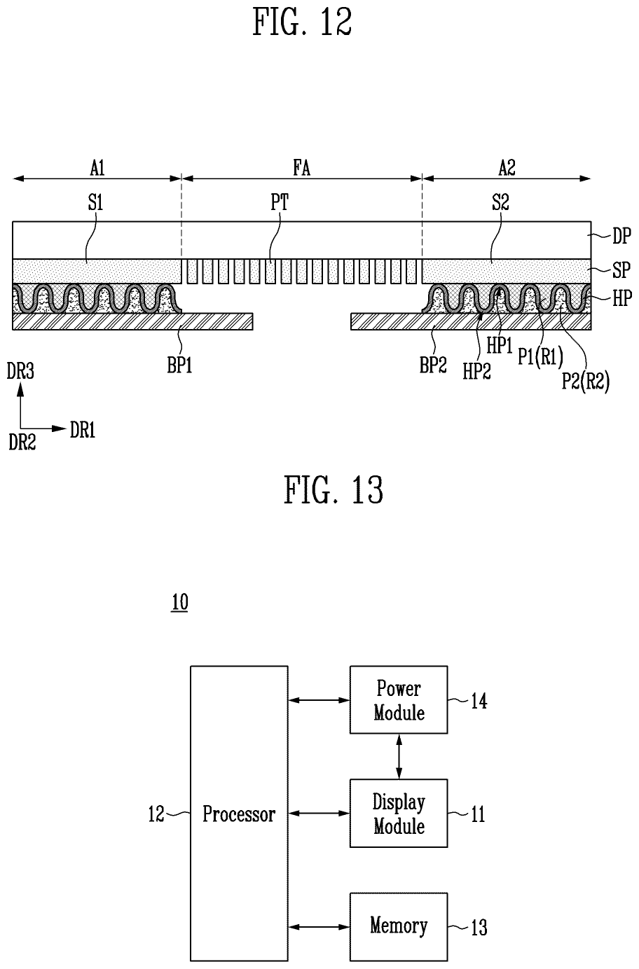

FIG. 12 is a cross-sectional view of a display device in accordance with an embodiment of the present disclosure.

Referring to FIG. 12, a heat dissipation resin R1 and R2 may be provided inside the cooling flow path P1 and P2. The heat dissipation resin R1 and R2 may be provided in the cooling flow path P1 and P2, for example, in the heat dissipation plate HP, to diffuse or cool heat emitted from the display panel DP. In an embodiment, the heat dissipation resin R1 and R2 may overlap the first area A1 and the second area A2. For example, the heat dissipation resin R1 and R2 may overlap the first area A1 and the second area A2 in the third direction DR3 in the unfolded state. The heat dissipation resin R1 and R2 may not overlap the folding area FA. For example, the heat dissipation resin R1 and R2 may not overlap the folding area FA in the third direction DR3 in the unfolded state, but the present disclosure is not limited thereto.

The heat dissipation resin R1 and R2 may include a first heat dissipation resin R1 provided in the first flow path P1 and a second heat dissipation resin R2 provided in the second flow path P2.

The first heat dissipation resin R1 and the second heat dissipation resin R2 may be separated from each other by the heat dissipation plate HP. The first heat dissipation resin R1 may be directly provided in a space between the support plate SP and the second bending portion HP2 of the heat dissipation plate HP. For example, the first heat dissipation resin R1 may be between the rear surface of the support plate SP and the top surface of the heat dissipation plate HP.

The second heat dissipation resin R2 may be directly provided in a space between the lower plates BP1 and BP2 and the first bending portion HP1 of the heat dissipation plate HP. For example, the second heat dissipation resin R2 may be between the top surfaces of the lower plates BP1 and BP2 and the rear surface of the heat dissipation plate HP.

In an embodiment, each of the first heat dissipation resin R1 and the second heat dissipation resin R2 may include a polymer resin and a filler having heat dissipation properties dispersed in the polymer resin. The first heat dissipation resin R1 and the second heat dissipation resin R2 may include the same material, but the present disclosure is not limited thereto. In some embodiments, the second heat dissipation resin R2 may be omitted, but the present disclosure is not limited thereto.

In accordance with the above-described embodiment, the cooling flow path P1 and P2 is formed by using the bending portions HP1 and HP2 of the heat dissipation plate HP, and the coolant F1 and F2 or the heat dissipation resin R1 and R2 is provided in the cooling flow path P1 and P2 so that heat dissipation characteristics of the display device DD can be improved. Accordingly, a product thickness and a product weight can be decreased while reducing or minimizing heat generation of the display device DD.

According to embodiments of the present disclosure, a coolant is provided in a cooling flow path formed by a bending portion of a heat dissipation plate so that heat dissipation characteristics of the display device can be improved.

A display device according to an embodiment is applicable to various types of electronic devices. In an embodiment, an electronic device includes the above-described display device and may further include other modules or devices having additional functions in addition to the display device.

FIG. 13 is a block diagram of an electronic device according to an embodiment. Referring to FIG. 13, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

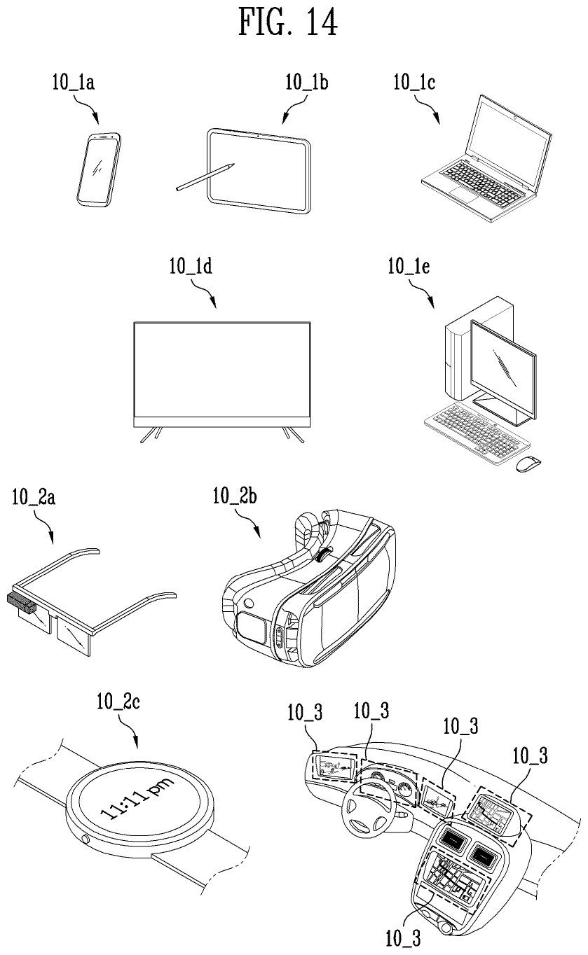

FIG. 14 shows schematic views of various embodiments of an electronic device.

Referring to FIG. 14, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

What is claimed is:

1. A display device comprising:
a display panel having a first area, a folding area, and a second area arranged along a first direction, the folding area being configured to be folded with respect to a folding axis defined along a second direction crossing the first direction;
a support plate on a rear surface of the display panel, the support plate having a pattern portion overlapping the folding area;
a heat dissipation plate on a rear surface of the support plate, the heat dissipation plate having a continuous bending portion; and
a first coolant between the bending portion and the support plate.

2. The display device of claim 1, wherein the bending portion is coupled to the support plate.

3. The display device of claim 1, wherein the bending portion overlaps the folding area.

4. The display device of claim 1, wherein the bending portion does not overlap the folding area.

5. The display device of claim 4, wherein the heat dissipation plate has a lattice portion overlapping the folding area.

6. The display device of claim 1, wherein the first coolant overlaps the first area and the second area.

7. The display device of claim 1, wherein the first coolant does not overlap the folding area.

8. The display device of claim 1, further comprising a lower plate on a rear surface of the heat dissipation plate.

9. The display device of claim 8, further comprising a second coolant between the bending portion and the lower plate.

10. The display device of claim 8, wherein the bending portion is coupled to the lower plate.

11. The display device of claim 1, further comprising an upper plate between the support plate and the heat dissipation plate.

12. The display device of claim 11, wherein the bending portion is coupled to the upper plate.

13. A display device comprising:
a display panel having a first area, a folding area, and a second area arranged along a first direction, the folding area being configured to be folded with respect to a folding axis defined along a second direction crossing the first direction;
a support plate on a rear surface of the display panel, the support plate having a pattern portion overlapping the folding area;
a lower plate on a rear surface of the support plate;
a heat dissipation plate between the support plate and the lower plate, the heat dissipation plate having a continuous bending portion;
a first flow path between the support plate and the bending portion; and
a second flow path between the lower plate and the bending portion.

14. The display device of claim 13, further comprising:
a first heat dissipation resin in the first flow path; and
a second heat dissipation resin in the second flow path.

15. The display device of claim 14, wherein the first heat dissipation resin and the second heat dissipation resin overlap the first area and the second area.

16. The display device of claim 14, wherein the first heat dissipation resin and the second heat dissipation resin do not overlap the folding area.

17. The display device of claim 13, wherein the bending portion comprises a first bending portion coupled to the support plate and a second bending portion coupled to the lower plate.

18. An electronic device comprising:
a display device comprising:
a display panel having a first area, a folding area, and a second area arranged along a first direction, the folding area being configured to be folded with respect to a folding axis defined along a second direction crossing the first direction;
a support plate on a rear surface of the display panel, the support plate having a pattern portion overlapping the folding area;
a heat dissipation plate on a rear surface of the support plate, the heat dissipation plate having a continuous bending portion; and
a first coolant between the bending portion and the support plate.

19. The electronic device of claim 18, further comprising a sensing layer on the display device, the sensing layer being configured to receive a user's touch as an input.

20. The electronic device of claim 18, wherein the bending portion of the heat dissipation plate forms two adjacent cooling channels separated from each other by the heat dissipation plate.
